(19) United States
(12) Patent Application Publication
(10) Pub. No.: US 2025/0380508 A1
(43) Pub. Date: Dec. 11, 2025

(54) SEMICONDUCTOR DEVICE

(71) Applicant: SAMSUNG ELECTRONICS CO., LTD., Suwon-si (KR)

(72) Inventors: Hyunkwan YU, Suwon-si (KR); Kichul KIM, Suwon-si (KR); Dongsuk SHIN, Suwon-si (KR); Jinnam KIM, Suwon-si (KR)

(73) Assignee: SAMSUNG ELECTRONICS CO., LTD., Suwon-si (KR)

(21) Appl. No.: 19/047,073

(22) Filed: Feb. 6, 2025

(30) Foreign Application Priority Data
Jun. 7, 2024 (KR) 10-2024-0074429

(51) Int. Cl. H10D 86/00; H10D 30/00; H10D 30/01; H10D 62/10; H10D 62/13; H10D 62/83; H10D 62/832; H10D 64/23; H10D 64/27; H10D 86/01

(52) U.S. Cl. CPC H10D 86/201; H10D 30/502; H10D 62/115; H10D 62/121; H10D 62/151; H10D 62/83; H10D 62/832; H10D 64/256; H10D 64/258; H10D 64/516; H10D 30/0191; H10D 86/01

(57) ABSTRACT

A semiconductor device includes an insulating base layer, a fin-type pattern on the insulating base layer and extending in a first direction, a plurality of channel structures on the fin-type pattern and spaced apart from each other in the first direction, each of the plurality of channel structures including a plurality of channel layers spaced apart from each other in a second direction that is perpendicular to the first direction, a plurality of gate structures respectively on the plurality of channel structures and extending in a third direction intersecting the first direction, source/drain patterns including a first source/drain pattern that is connected to side surfaces of some of the plurality of channel structures, internal spacers between the plurality of gate structures and the source/drain patterns, and a plurality of bottom isolation patterns respectively below the plurality of gate structures and between the insulating base layer and the fin-type pattern.

### CROSS-REFERENCE TO RELATED APPLICATION(S)

This application is based on and claims priority to Korean Patent Application No. 10-2024-0074429, filed on Jun. 7, 2024, in the Korean Intellectual Property Office, the disclosure of which is incorporated herein by reference in its entirety.

### BACKGROUND

Example embodiments of the disclosure relate to a semiconductor device.

As demand for high performance, high speed, and/or multifunctionality in semiconductor devices increases, the degree of integration of semiconductor devices has increased. In accordance with the trend toward a high degree of integration of semiconductor devices, a semiconductor device having a Backside Power Delivery Network (BSPDN) structure in which a power rail is disposed on a backside of a wafer has been developed. Additionally, efforts have been made to develop semiconductor devices having a three-dimensional channel structure in order to overcome the limitation of operating characteristics due to a size reduction of such devices, such as a planar metal-oxide-semiconductor (MOS) field effect transistor (FET) (MOSFET).

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device having improved electrical characteristics and reliability.

Additional aspects will be set forth in part in the description which follows and, in part, will be apparent from the description, or may be learned by practice of the presented embodiments.

According to an aspect of an example embodiment, a semiconductor device may include an insulating base layer, a fin-type pattern on the insulating base layer and extending in a first direction, a plurality of channel structures on the fin-type pattern and spaced apart from each other in the first direction, each of the plurality of channel structures including a plurality of channel layers spaced apart from each other in a second direction that is perpendicular to the first direction, a plurality of gate structures respectively on the plurality of channel structures and extending in a third direction intersecting the first direction, source/drain patterns including a first source/drain pattern that is connected to side surfaces of some of the plurality of channel structures, internal spacers between the plurality of gate structures and the source/drain patterns, a plurality of bottom isolation patterns respectively below the plurality of gate structures and between the insulating base layer and the fin-type pattern, the plurality of bottom isolation patterns being spaced apart from each other in the first direction, and including a material that is the same as a material of the internal spacers, and a lower contact structure penetrating the insulating base layer and connected to the first source/drain pattern, the lower contact structure passing between first bottom isolation patterns among the plurality of bottom isolation patterns that are adjacent to the first source/drain pattern.

According to an aspect of an example embodiment, a semiconductor device may include an insulating base layer, a fin-type structure on the insulating base layer and extending in a first direction, a plurality of channel structures on the fin-type structure and spaced apart from each other in the first direction, and each of the plurality of channel structures including a plurality of channel layers spaced apart from each other in a second direction perpendicular to the first direction, a plurality of gate structures respectively on the plurality of channel structures and extending in a third direction intersecting the first direction, source/drain patterns including a first source/drain pattern that is connected to side surfaces of some of the plurality of channel structures, internal spacers between the plurality of gate structures and the source/drain patterns, and a lower contact structure penetrating the insulating base layer and connected to the first source/drain pattern, where the fin-type structure includes a first fin-type pattern and a second fin-type pattern on the insulating base layer, a plurality of first bottom isolation patterns respectively below the plurality of gate structures and spaced apart from each other in the first direction, the plurality of first bottom isolation patterns being between the insulating base layer and the first fin-type pattern, and a plurality of second bottom isolation patterns respectively below the plurality of gate structures and spaced apart from each other in the first direction, the plurality of second bottom isolation patterns being between the first fin-type pattern and the second fin-type pattern, where each of the plurality of first bottom isolation patterns and the plurality of second bottom isolation patterns includes a material that is the same as a material of the internal spacers, and where the lower contact structure penetrates between third bottom isolation patterns among the plurality of first bottom isolation patterns that are adjacent to the first source/drain pattern, and between fourth bottom isolation patterns among the plurality of second bottom isolation patterns that are adjacent to the first source/drain pattern.

According to an aspect of an example embodiment, a semiconductor device may include an insulating base layer, a plurality of channel layers on the insulating base layer and spaced apart from each other, a gate structure surrounding the plurality of channel layers, a first source/drain pattern and a second source/drain pattern on the insulating base layer, internal spacers in the gate structure and between the plurality of channel layers and the first source/drain pattern and the second source/drain pattern, a bottom isolation pattern on an upper surface of the insulating base layer and below the plurality of channel layers, the bottom isolation pattern including a material that is the same as a material of the internal spacers, a first contact structure penetrating the insulating base layer, contacting a first side of the bottom isolation pattern and connected to the first source/drain pattern, a second contact structure connected to the second source/drain pattern, and a bottom sacrificial pattern below the second source/drain pattern, on a level that is the same as a level of the bottom isolation pattern, and connected to a second side of the bottom isolation pattern.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating a semiconductor device according to one or more embodiments;

FIG. 2 is a cross-sectional view taken along line I-I′ of the semiconductor device of FIG. 1 according to one or more embodiments;

FIGS. 3A, 3B and 3C are cross-sectional views taken along line II1-II1′, II2a-II2a′, and II2b-II2b′ of the semiconductor device of FIG. 1, respectively, according to one or more embodiments;

FIGS. 4A and 4B are partially enlarged views illustrating “A1” and “B1” of FIG. 2, respectively, according to one or more embodiments;

FIG. 5 is a partially enlarged view illustrating “C” of FIG. 2, according to one or more embodiments;

FIG. 6 is a cross-sectional view illustrating a semiconductor device according to one or more embodiments;

FIGS. 7A and 7B are partially enlarged views illustrating “A2” and “B2” of FIG. 6, respectively, according to one or more embodiments;

FIG. 8 is a cross-sectional view illustrating a semiconductor device according to one or more embodiments;

FIG. 9 is a partially enlarged view illustrating “B3” of FIG. 8 according to one or more embodiments;

FIG. 10 is a cross-sectional view illustrating a semiconductor device according to one or more embodiments;

FIGS. 11A to 11D are cross-sectional views illustrating a method of manufacturing a semiconductor device according to one or more embodiments;

FIGS. 12A to 12D are cross-sectional views illustrating a method of manufacturing a semiconductor device according to one or more embodiments;

FIGS. 13A to 13D are cross-sectional views illustrating a method of manufacturing a semiconductor device according to one or more embodiments; and

FIGS. 14A to 14E are cross-sectional views illustrating a method of manufacturing a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

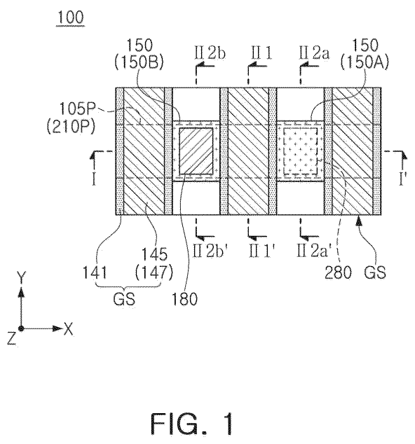

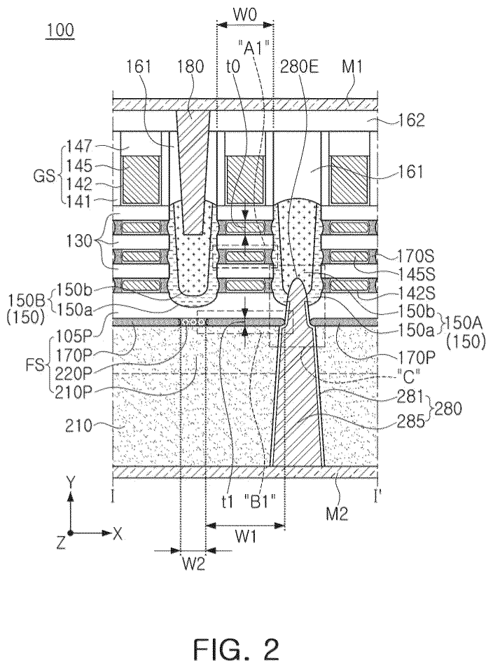

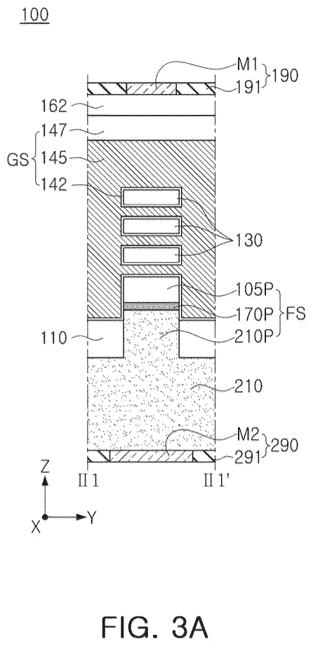

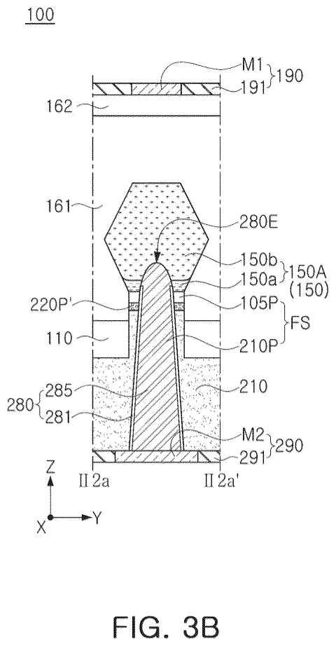

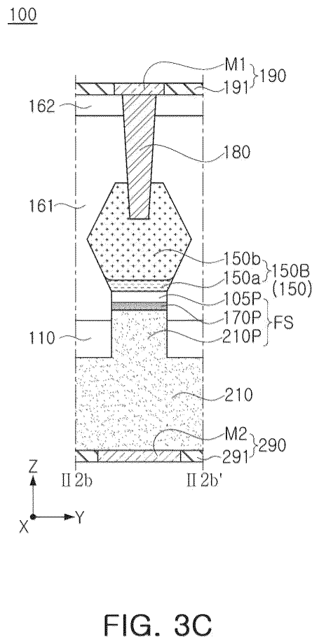

FIG. 1 is a plan view illustrating a semiconductor device according to one or more embodiments. FIG. 2 is a cross-sectional view taken along line I-I′ of the semiconductor device of FIG. 1 according to one or more embodiments. FIGS. 3A, 3B and 3C are cross-sectional views taken along line II1-II1′, II2a-II2a′, and II2b-II2b′ of the semiconductor device of FIG. 1, respectively, according to one or more embodiments.

Referring to FIGS. 1, 2, and 3A to 3C, a semiconductor device 100 according to one or more embodiments may include an insulating base layer 210, a fin-type structure FS extending in a first direction on the insulating base layer 210, a plurality of channel layers 130 stacked and spaced apart from each other in a direction (e.g., a Z-direction) that is perpendicular to an upper surface of the insulating base layer 210, on one region of the fin-type structure FS, a gate structure GS extending in a second direction (e.g., a Y-direction) that intersects the first direction (e.g., an X-direction), and surrounding a plurality of channel layers 130, and a plurality of source/drain patterns 150A and 150B respectively connected to both side surfaces of the plurality of channel layers 130 in the first direction (e.g., the X-direction).

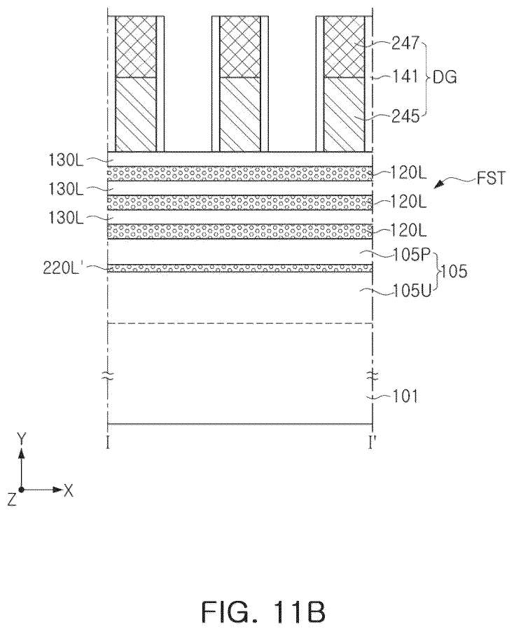

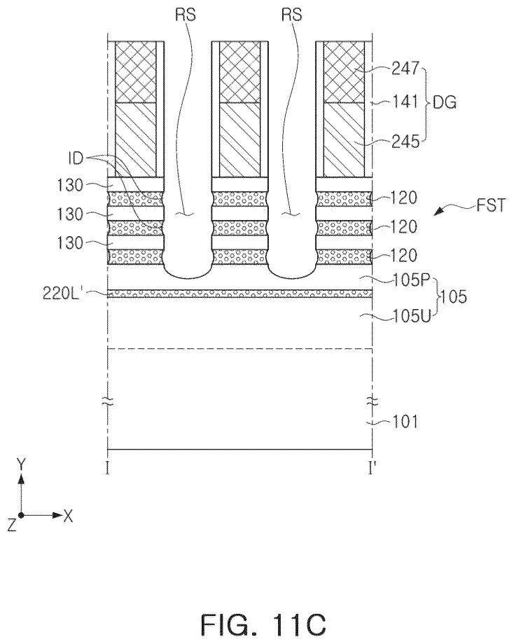

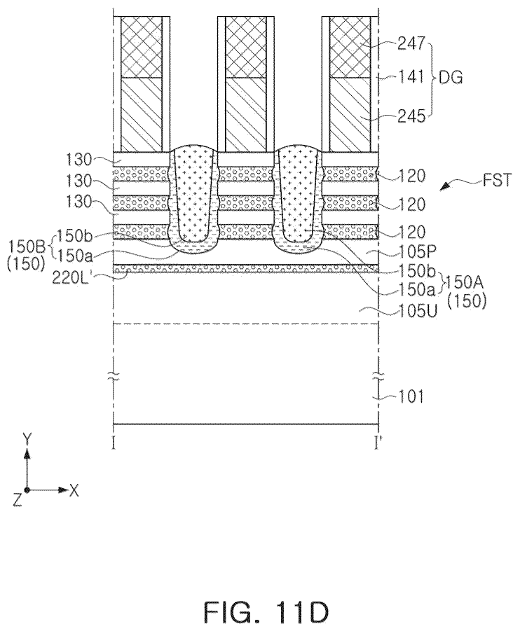

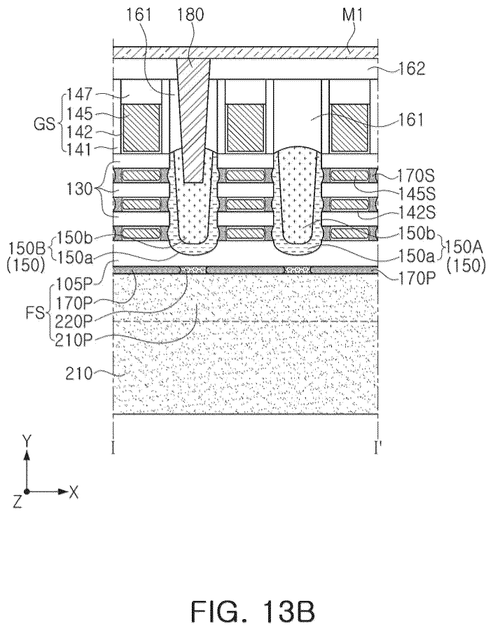

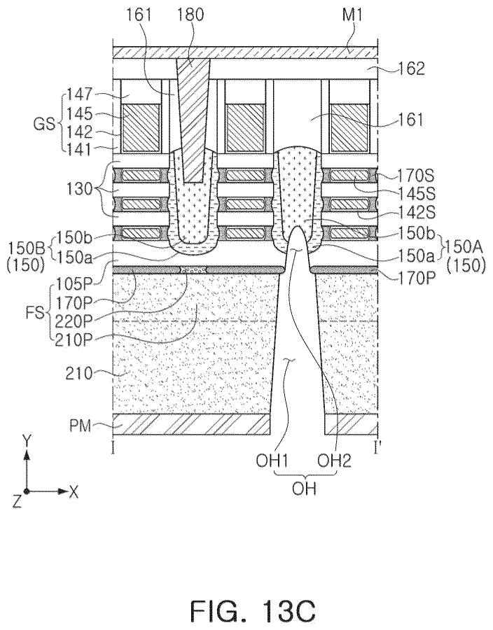

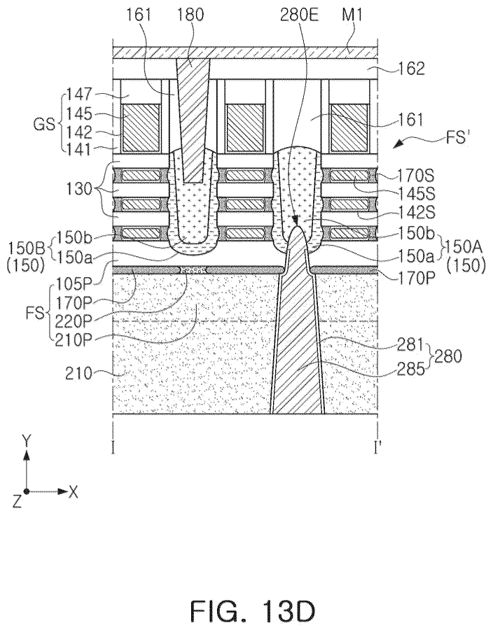

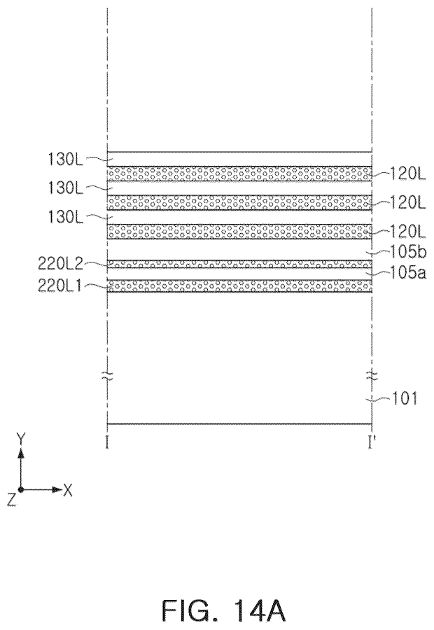

In one or more embodiments, the insulating base layer 210 may include an insulating pattern 210P protruding from a region corresponding to a fin-type pattern 105P on an upper surface of the insulating base layer 210. The insulating base layer 210 may be a layer formed in an additional process (e.g., see FIG. 13B) after removing a substrate (e.g., see ‘101’ of FIG. 11A) including a semiconductor material (e.g., see FIG. 13A), or a layer formed by oxidizing the substrate in a series of manufacturing processes of the semiconductor device 100. The insulating base layer 210 may include an insulating material such as an oxide or a nitride. For example, the insulating base layer 210 may be Spin-on Hardmask (SOH), Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or combinations thereof. The insulating base layer 210 may be formed using a chemical vapor deposition (CVD), a flowable-CVD process, or a spin coating process.

Referring to FIGS. 2 and 3A to 3C, the insulating base layer 210 may include a fin-type structure FS extending in the first direction (e.g., X-direction). A device isolating layer 110 may define a fin-type structure FS on the insulating base layer 210. The fin-type structure FS may include an insulating pattern 210P, a fin-type pattern 105P, and a plurality of bottom isolation patterns 170P therebetween. The device isolating layer 110 may be disposed on the insulating base layer 210 so as to cover both side surfaces of the insulating pattern 210P. An upper region of the insulating pattern 210P may be exposed from an upper surface of the device isolating layer 110. The insulating pattern 210P may be a structure corresponding to a lower region of an active pattern, and the insulating pattern 210P may be obtained in a process of replacing the semiconductor substrate described above with the insulating base layer 210 (see FIGS. 13A and 13B). Referring to FIGS. 3A to 3C, the insulating pattern 210P is illustrated as having a visually distinct interfacial with the device isolating layer 105, but in one or more embodiments, the insulating base layer 210 may be formed of the same material (e.g., silicon oxide) as the device isolating layer 110, and in this case, the interfacial between the insulating pattern 210P and the device isolating layer 105 may be difficult to visually identify.

Referring to FIGS. 2 and 3A, as described above, the plurality of channel layers 130 may be stacked and spaced apart from each other on the fin-type structure FS, particularly the fin-type pattern 105P. The semiconductor device 100 may include source/drain patterns 150, i.e., first and second source/drain patterns 150A and 150B, respectively connected to both side surfaces of the plurality of channel layers 130 in the first direction (e.g., X-direction). In one or more embodiments, the plurality of channel layers 130 may have a width that is identical to or similar to a width of a fin-type pattern 150P in the second direction (e.g., Y-direction). The number of channel layers 130 are illustrated as being three, but the number and shape thereof may be variously changed. In one or more embodiments, the widths of the plurality of channel layers 130 may be somewhat different from each other. For example, widths of uppermost and lowermost channel layers may be greater than the widths of the channel layers disposed therebetween.

The plurality of channel layers 130 may include a semiconductor material that may provide a channel region of a transistor. For example, the plurality of channel layers 130 may include at least one of silicon (Si), silicon germanium (SiGe), and germanium (Ge). In one or more embodiments, the plurality of channel layers 130 may include silicon.

As illustrated in FIGS. 2 and 3A, the gate structure GS adopted in one or more embodiments may include a gate electrode 145 extending in the second direction (e.g., Y-direction) and surrounding the plurality of channel layers 130, a gate insulating film 142 disposed between the gate electrode 145 and the plurality of channel layers 130, gate spacers 141 disposed on both side surfaces of a portion of the gate electrode 145 disposed on the uppermost channel layer, and a gate capping layer 147 disposed on the gate electrode 145 between the gate spacers 141.

The gate electrode 145 may include a conductive material. For example, the gate electrode 145 may include at least one of W, Ti, Ta, Mo, TiN, TaN, WN, TiON, TiAlC, TiAlN, and TaAlC. In one or more embodiments, the gate electrode 145 may include a semiconductor material, such as doped polysilicon. At least one of the gate electrodes 145 may include a multilayer structure formed of different materials.

The gate insulating film 142 may include a dielectric material. For example, the gate insulating film 142 may include an oxide, a nitride, or high-K material. The high-K material may refer to a dielectric material having a higher dielectric constant than a silicon oxide film (SiO₂), and the high-K material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In one or more embodiments, the gate insulating film 142 may include two or more different dielectric films.

The gate spacers 141 may include an insulating material. For example, the gate spacers 141 may include at least one of silicon oxide, silicon nitride, and silicon oxynitride. In one or more embodiments, the gate spacers 141 may include a multilayer structure formed of different materials. The gate capping layer 147 may include, for example, silicon nitride, silicon oxynitride, silicon carbon nitride, or silicon oxycarbon nitride.

The gate structure GS according to one or more embodiments may include internal spacers 170S. The internal spacers 170S may be disposed on both sides of a gate electrode portions 145S disposed between the plurality of channel layers 130 and between the lowermost channel layer (and the fin-type pattern 105P). The gate electrode portions 145S may be surrounded by gate insulating portions 142S in the first direction (e.g., the X-direction). The gate electrode portions 145S and the gate insulating portions 142S may be spaced apart from the first and second source/drain patterns 150A and 150B by the internal spacers 170S.

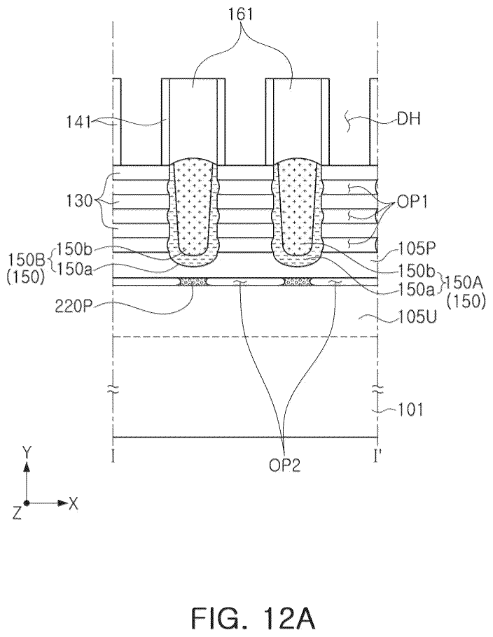

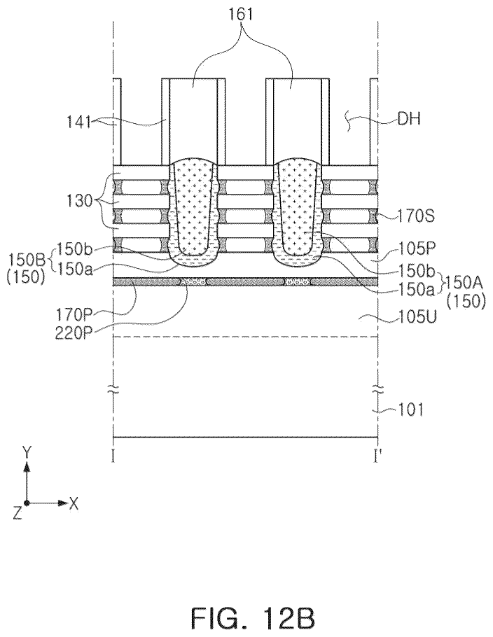

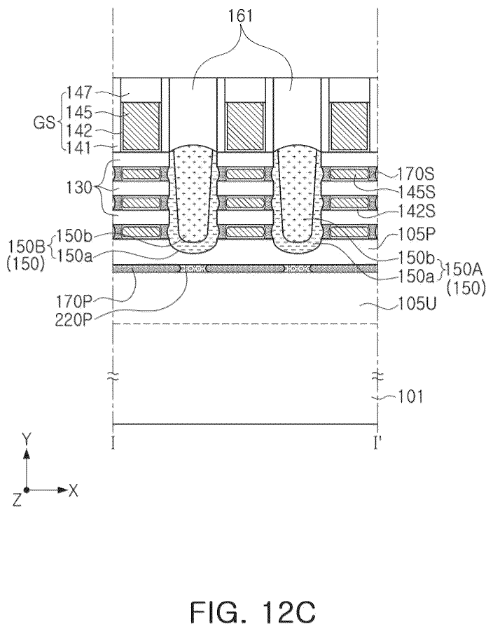

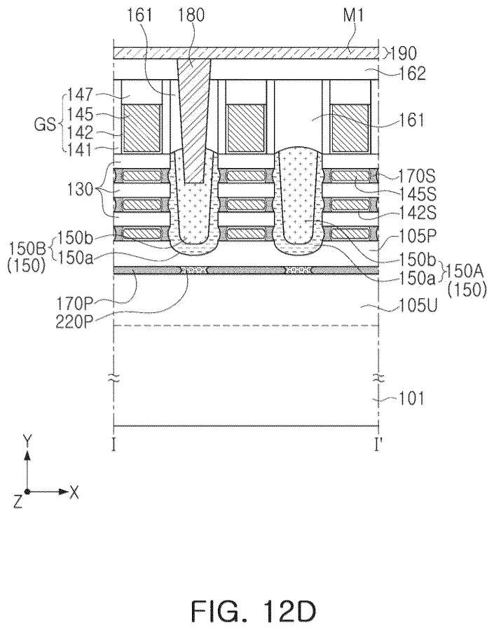

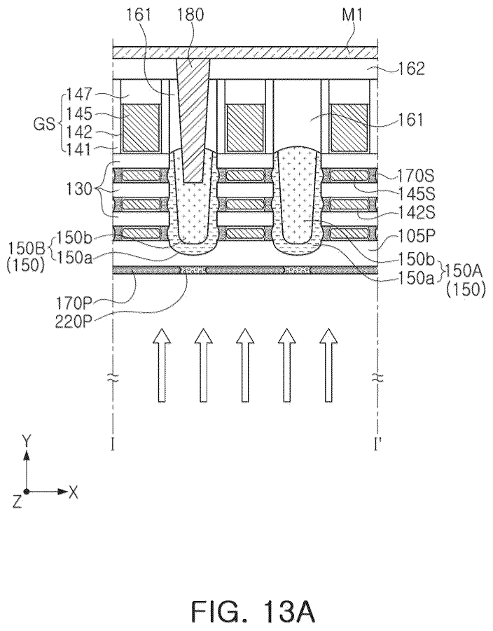

The internal spacers 170S adopted in one or more embodiments may be provided after a formation process of the source/drain patterns 150. For example, the internal spacers 170S may be formed along with the bottom isolation patterns 170P during a formation process of the gate structure GS (see FIG. 12B). Accordingly, as described above, the internal spacers 170S may include the material as a material of the bottom isolation patterns 170P. For example, the internal spacers 170S may include a low-K dielectric material such as an oxide, a nitride, and an oxynitride.

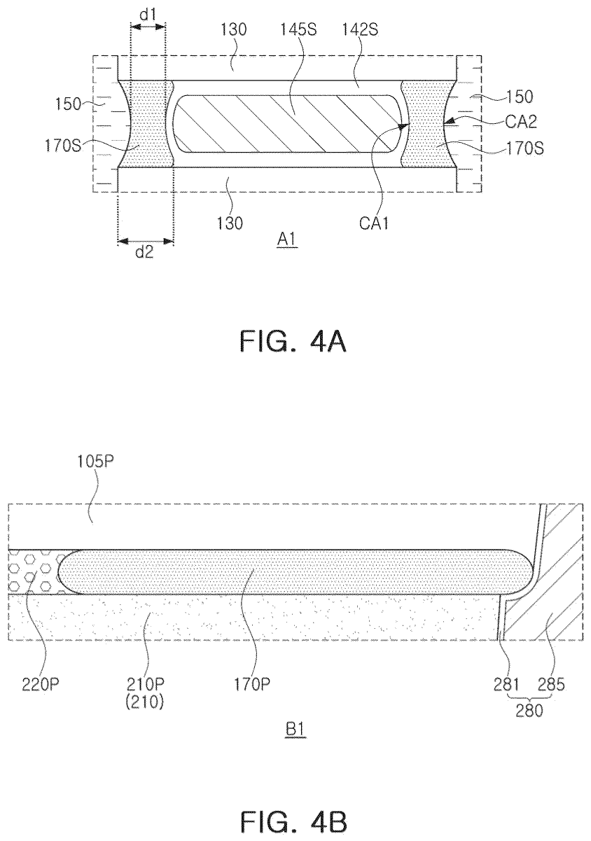

FIG. 4A is a partially enlarged view illustrating “A1” of FIG. 2, according to one or more embodiments.

Referring to FIG. 4A along with FIG. 2, the internal spacers 170S may have a first side surface CA1 contacting the gate insulating portion 142S of the gate structure GS, and each of the first side surfaces CA1 may have a concave surface. In one or more embodiments, a middle portion of each of the internal spacers 170S may have a width d1 smaller than widths d2 of an upper end and a lower end thereof, which differs internal spacers that are formed before forming the source/drain patterns 150. Additionally, as described above, since the internal spacers 170S are formed after forming the source/drain patterns 150, the source/drain patterns 150 may have a structure in which the source/drain patterns 150 are somewhat indented between the channel layers 130. Accordingly, the internal spacers 170S may have second side surfaces CA2 contacting the source/drain patterns 150, and each of the second side surfaces CA2 may also have a concave surface.

As illustrated in FIG. 2, the first and second source/drain patterns 150A and 150B may be disposed on regions of the insulating pattern 210P at both sides of the gate structures GS, respectively. Regions of the insulating pattern 210P in which the first and second source/drain patterns 150A and 150B are formed may be slightly recessed regions. The first and second source/drain patterns 150A and 150B may be connected to both side surfaces of the plurality of channel layers 130, which are channel regions, as described above, respectively.

Referring to FIGS. 2, 3B and 3C, each of the first and second source/drain patterns 150A and 150B of one or more embodiments may include a first epitaxial layer 150a and a second epitaxial layer 150b on the first epitaxial layer 150a. The first epitaxial layer 150a may directly contact side surfaces of the plurality of channel layers 130.

The first epitaxial layer 150a and the second epitaxial layer 150b may include different materials. For example, in the case of a p-type metal-oxide-semiconductor (MOS) field effect transistor (FET) (MOSFET) (PMOSFET), the first and second epitaxial layers 150a and 150b may include SiGe having different Ge components (e.g., the second epitaxial layer 150b may contain a higher Ge content), or the first and second epitaxial layers 150a and 150b may include Si and SiGe, respectively. However, in the case of an n-type MOSFET (NMOSFET), both the first/second epitaxial layers 150a and 150b may include Si. In one or more embodiments, the first epitaxial layer 150a and the second epitaxial layer 150b may include different types of impurities or the same impurities at different concentrations.

Referring to FIG. 2, the plurality of bottom isolation patterns 170P may be spaced apart from each other in the first direction (e.g., X-direction), between the insulating pattern 210P and the fin-type pattern 105P. The plurality of bottom isolation patterns 170P may be positioned below the plurality of gate structures GS, respectively. In one or more embodiments, each of the bottom isolation patterns 170P may have a thickness t1 smaller than a gap t0 of the plurality of channel layers 130, and a width W1 of each of the bottom isolation patterns 170P in the first direction (e.g., X-direction) may be greater than a width W0 of each of the plurality of channel layers 130 in the first direction (e.g., X-direction).

In one or more embodiments, the bottom isolation patterns 170P may be formed together during a formation process of the internal spacers 170S (see FIG. 12B). The bottom isolation patterns 170P may include the same material as the internal spacer 170S. For example, the bottom isolation patterns 170P may include a low-K dielectric material such as an oxide, a nitride, and an oxynitride.

In one or more embodiments, the first source/drain pattern 150A among the plurality of source/drain patterns 150 may be connected to a lower contact structure 280 penetrating through the insulating base layer 210. The lower contact structure 280 may be connected to the first source/drain pattern 150A by passing between bottom isolation patterns 170P adjacent to the first source/drain pattern 150A, among the bottom isolation patterns 170P. The adjacent bottom isolation patterns 170P may be used as a self-alignment structure that aligns a position of the lower contact structure 280.

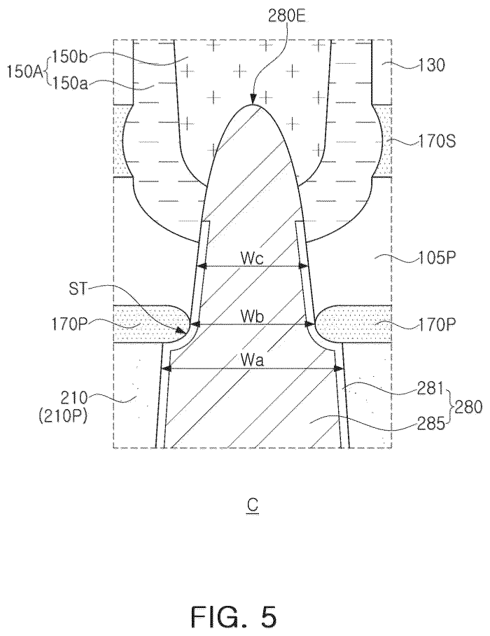

FIG. 4B is a partially enlarged view illustrating “B1” of FIG. 2, according to one or more embodiments. FIG. 5 is a partially enlarged view illustrating “C” of FIG. 2, according to one or more embodiments.

Referring to FIG. 3B, FIG. 4B and FIG. 5 along with FIG. 2, the lower contact structure 280 may include a contact extension portion 280E connected to the first source/drain pattern 150A by passing through the region of the adjacent bottom isolation patterns 170P through the insulating base layer 210. The adjacent bottom isolation patterns 170P may be aligned so that the contact extension portion 280E is directed toward an approximate center of a bottom of the first source/drain pattern 150A. In this manner, a width Wb of a portion in which the contact extension portion 280E begins may be defined by a space between the adjacent bottom isolation patterns 170P in the first direction (e.g., X-direction).

Referring to FIG. 5 along with FIG. 2, the lower contact structure 280 may have a step structure ST in the portion in which the contact extension portion 280E begins. The width Wb of the contact extension portion 280E defined between the adjacent bottom isolation patterns 170P may be smaller than a width Wa of another portion of the lower contact structure 280 adjacent to the insulating base layer 210. The contact extension portion 280E may have a width Wc similar to or smaller than the defined width Wb.

Referring to FIG. 3B, it is illustrated that a width of the lower contact structure 280 in the second direction (e.g., Y-direction) may be smaller than a width of the fin-type structure FS in the second direction (e.g., Y-direction), and some bottom sacrificial patterns 220P′ remain around the lower contact structure 280, but embodiments are not limited thereto, and in one or more embodiments, the remaining bottom sacrificial patterns may be minimal or almost non-existent depending on etching conditions for forming a contact hole. In one or more embodiments, in a contact hole forming process (see FIG. 13C), the width of the lower contact structure in the second direction may be designed to correspond to the width of the fin-type structure FS in the second direction, and as a result, relevant bottom sacrificial patterns may be removed. Additionally, as illustrated in FIG. 3B, in a cross-section in the second direction (e.g., Y-direction), the lower contact structure 280 may have a side surface having a relatively small step portion or almost no step portion, unlike the cross-sections in FIGS. 2 and 5.

In one or more embodiments, the fin-type pattern 105P may include a semiconductor material such as silicon as a region remaining from the active pattern, as described above. In this case, the lower contact structure 280 may include a contact plug 285 and an insulating liner 281 disposed on a side surface of the contact plug 285. The lower contact structure 280 may be electrically isolated from the fin-type pattern 105P by the insulating liner 281. For example, the contact plug 285 may include a conductive material such as Cu, Co, Mo, Ru, W, or alloys thereof. For example, the insulating liner 281 may include SiO₂, SiN, SiCN, SiC, SiCOH, SiON, Al₂O₃, AlN, or combinations thereof.

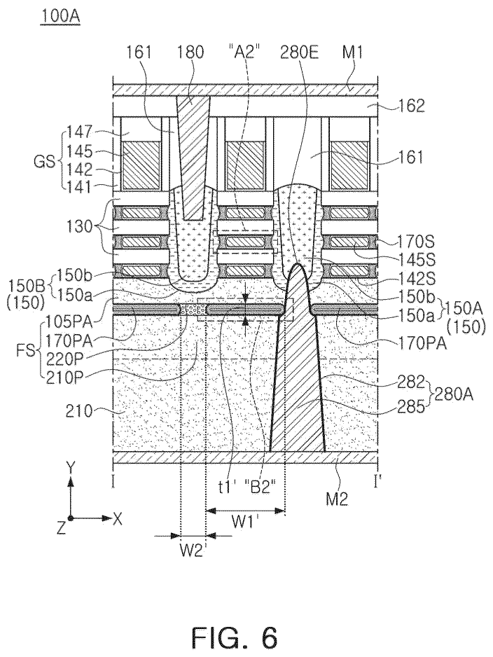

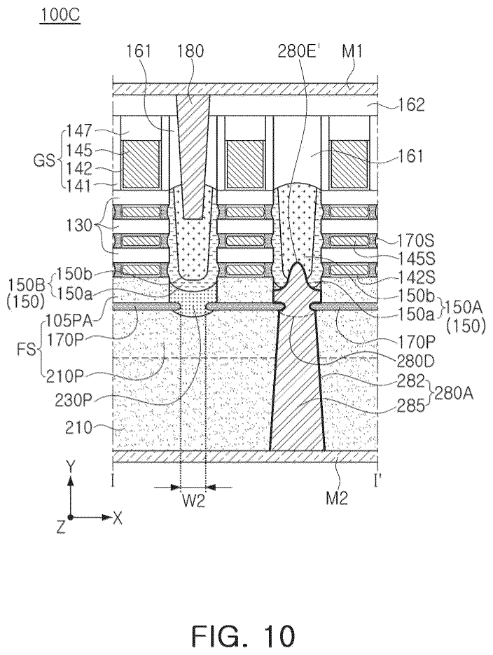

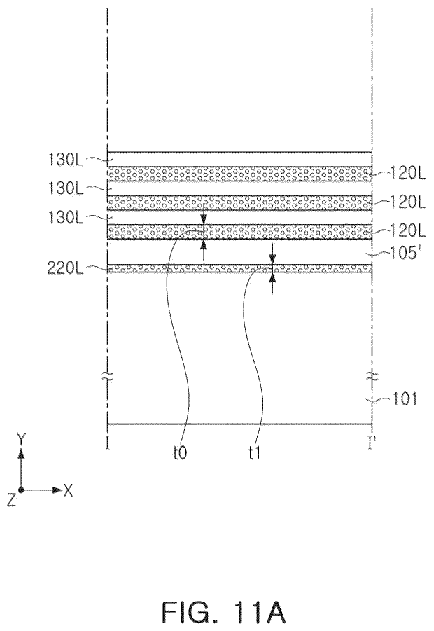

In one or more embodiments, the fin-type pattern 105P may include silicon oxide. The remaining active pattern may be oxidized using an additional thermal oxidation process, and the like. In this case, the lower contact structure 280 may include a contact plug 285 and a conductive barrier 282 disposed on a surface of the contact plug 285 (see FIGS. 6 and 10).

The semiconductor device 100 according to one or more embodiments may include an upper contact structure 180 connected to the second source/drain pattern 150B between a plurality of gate structures GS.

Referring to FIGS. 2 and 3C, the fin-type structure FS may further include a bottom sacrificial pattern 220P disposed between bottom sacrificial patterns 170P adjacent to the second source/drain pattern 150B, among the bottom sacrificial patterns 170P. The bottom sacrificial pattern 220P may be disposed on the same level as the bottom sacrificial patterns 170P below the second source/drain pattern 150B. In one or more embodiments, the bottom sacrificial patterns 170P may have a convex-shaped side surface toward the bottom sacrificial pattern 220P.

In one or more embodiments, a width W2 of each of the bottom sacrificial patterns 220P in the first direction (e.g., X-direction) may be smaller than the width W1 of each of the bottom isolation patterns 170P in the first direction (e.g., X-direction). The bottom sacrificial pattern 220P may be used as a sacrificial structure defining a formation region of the lower contact structure 280, and the bottom sacrificial pattern 220P under the second source/drain pattern 150B may be removed to define a hole for forming the lower contact structure 280 (see FIG. 13C).

Accordingly, the width W2 of the bottom sacrificial pattern 220P in the first direction (e.g., X-direction) may be substantially equal to the width Wb of a portion between the bottom isolation patterns 170P adjacent to the first source/drain pattern 150A of the lower contact structure 280 (see FIGS. 2 and 5).

The bottom sacrificial pattern 220P remaining in a final structure may be disposed below the first source/drain pattern 150A connected to the upper contact structure 180.

The bottom sacrificial pattern 220P may include materials of the plurality of channel layers 130 and the fin-type pattern 105P and selectively removable materials. For example, the bottom sacrificial pattern 220P may include silicon germanium, and the plurality of channel layers 130 may include silicon. In one or more embodiments, the fin-type pattern 105P may also include silicon or silicon oxide oxidized from silicon.

The semiconductor device 100 according to one or more embodiments may further include a first interlayer insulating layer 161 disposed on the device isolating layer 110 to cover the first and second source/drain patterns 150A and 150B and a second interlayer insulating layer 162 covering the gate structure GS on the first interlayer insulating layer 161. For example, the first and second interlayer insulating layers 161 and 162 may be SOH, FOX, TOSZ, USG, BSG, PSG, BPSG, PETEOS, FSG, HDP oxide, PEOX, FCVD oxide, or combinations thereof. The first and second interlayer insulating layers 161 and 162 may be formed using chemical vapor deposition, a fluid CVD process, or a spin coating process.

Referring to FIGS. 2 and 3B, the contact extension portion 280E of the lower contact structure 280 may contact the second epitaxial layer 150b. An upper portion of the lower contact structure 280 may horizontally overlap with a lowermost channel layer, among the channel layers 130, or be disposed on a level higher than a level of the lowermost channel layer.

Referring to FIGS. 2 and 3C, a lower portion of the upper contact structure 180 may horizontally overlap with an uppermost channel layer, among the channel layers 130, or be disposed on a level lower than a level of the uppermost channel layer. The upper contact structures 180 may include a contact plug and a conductive barrier surrounding the contact plug. For example, the contact plug may include Cu, Co, Mo, Ru, W or alloys thereof. For example, the conductive barrier may include Ta, TaN, Mn, MnN, WN, Ti, TiN or combinations thereof.

The semiconductor device 100 according to one or more embodiments may have a double-sided interconnection structure including a front-side interconnection structure 190 and a back-side interconnection structure 290. The front-side interconnection structure 190 is provided on an upper surface of the semiconductor device 100, and the back-side interconnection structure is provided on a lower surface of the semiconductor device 100.

The front-side interconnection structure 190 may include an upper interconnection insulating layer 191 and an upper interconnection line M1 disposed in the upper interconnection insulating layer 191. Similarly, the back-side interconnection structure 290 may include a lower interconnection insulating layer 291 and a lower interconnection line M2 disposed in the lower interconnection insulating layer 291. For example, the upper and lower interconnection insulation layers 191 and 291 may include silicon oxide, silicon oxynitride, SiOC, SiCOH, or combinations thereof. For example, the upper and lower interconnection lines M1 and M2 may include copper or a copper-containing alloy. In one or more embodiments, the lower interconnection line M2 may be provided as a power line for power transmission, and may supply power for a device operation to the first source/drain pattern 150A through the lower contact structure 280.

The bottom isolation pattern 170P and the bottom sacrificial pattern 220P may be introduced as a self-alignment structure of the lower contact structure 280, and may be implemented in various forms in various example embodiments (see FIGS. 6 to 9).

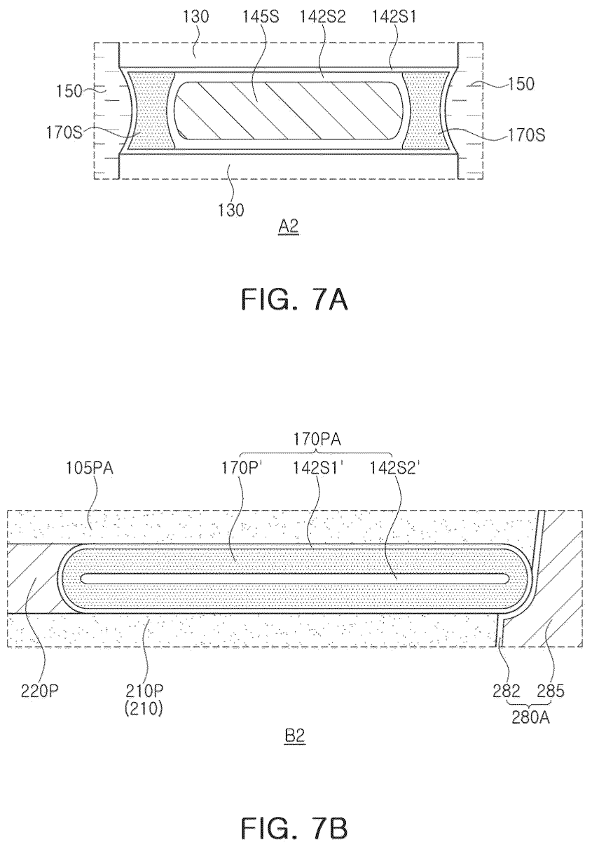

FIG. 6 is a cross-sectional view illustrating a semiconductor device according to one or more embodiments. FIGS. 7A and 7B are partially enlarged views illustrating “A2” and “B2” of FIG. 6, respectively, according to one or more embodiments.

Referring to FIGS. 6, 7A, and 7B, a semiconductor device 100A according to one or more embodiments may be similar to the semiconductor device 100 illustrated in FIGS. 1 to 5, except that the gate insulating film includes a plurality of insulating layers 142S1 and 142S2, a bottom isolation pattern 170PA further includes a plurality of insulating layers 142S1 and 142S2, a fin-type pattern 105PA is provided as an insulating structure, and a lower contact structure 280A is formed without an insulating liner. Description of aspects the same as or similar to those described above may be omitted.

The gate insulating film in one or more embodiments may include an interfacial insulating film 142S1 and a high-k dielectric film 142S2. The interfacial insulating film 142S1 may be formed before forming an internal spacer 170S, and the high-K dielectric film 142S2 may be formed after forming the internal spacer 170S and before forming the gate electrode 145. Referring to FIGS. 6 and 7A, each of the internal spacers 170S may be disposed between the interfacial insulating film 142S1 and the high-K dielectric film 142S2. The high-K dielectric film 142S2 may surround the gate electrode 145S in the second direction (e.g., the Y-direction) between the internal spacer 170S and the gate electrode 145S.

In one or more embodiments, the interfacial insulating film 142S1 and the internal spacer 170S may include the same material, such as silicon oxide. In one or more embodiments, the interfacial insulating film 142S1 and the internal spacer 170S may comprise different materials. For example, the interfacial insulating film 142S1 may include silicon oxide, and the internal spacer 170S may include silicon nitride or silicon oxynitride.

In one or more embodiments, the bottom isolation pattern 170PA may have a plurality of layer structures. Referring to FIGS. 6 and 7B, the bottom isolation pattern 170PA may further include the same material layers 142S1′ and 142S2′ as each of the interfacial insulating film 142S1 and the high-K dielectric film 142S2, as well as the same material portion 170P′ as the internal spacer 170S. For example, the bottom isolation pattern 170PA may include first to third insulating films 142S1, 170P′ and 142S2 sequentially from an internal surface thereof. The first insulating film 142S1′ may include the same material as a material of the interfacial insulating film 142S1, the second insulating film 170P′ includes the same material as a material of the internal spacer 170S, and the third insulating film 142S2′ may include the same material as a material of the high-K dielectric film 142S2. In one or more embodiments, a thickness of the second insulating film 170P′ may be greater than a thickness of each of the first and third insulating films 142S1′ and 142S2′. In one or more embodiments, the bottom isolation pattern 170PA may have a thickness t1′ and/or a width W1′ slightly greater than a thickness of the bottom isolation pattern 170P described above.

In one or more embodiments, the fin-type pattern 105PA may be provided as an insulating structure. For example, the fin-type pattern 105PA may include silicon oxide. In one or more embodiments, the remaining active pattern may be oxidized through an oxidation process such as an additional thermal oxidation process and may be converted into a thermal oxide layer. In this case, the lower contact structure 280 may be provided without an insulating liner. The lower contact structure 280 may include a contact plug 285 and a conductive barrier 282 disposed on a surface of the contact plug 285. For example, the contact plug 285 may include Cu, Co, Mo, Ru, W, or alloys thereof. For example, the conductive barrier 282 may include Ta, TaN, Mn, MnN, WN, Ti, TiN, or combinations thereof.

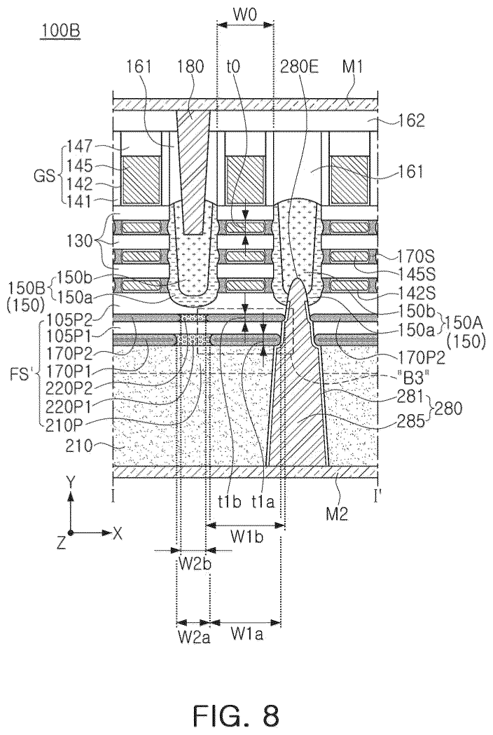

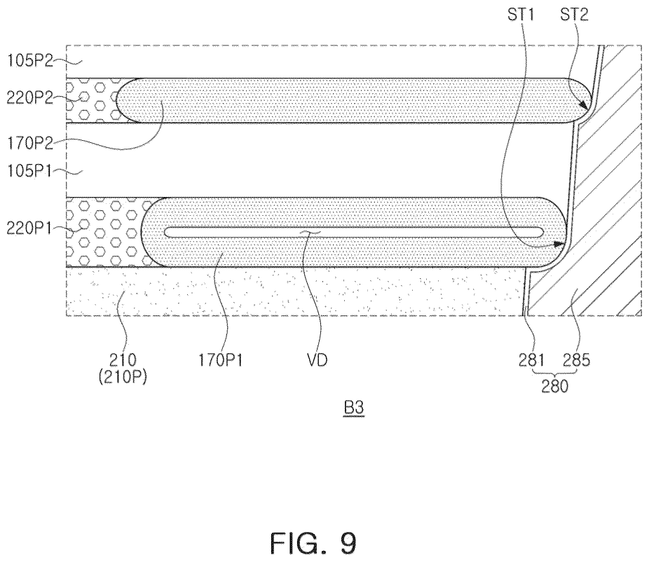

FIG. 8 is a cross-sectional view illustrating a semiconductor device according to one or more embodiments. FIG. 9 is a partially enlarged view illustrating “B3” of FIG. 8 according to one or more embodiments.

Referring to FIG. 8, a semiconductor device 100B according to one or more embodiments may be understood as being similar to the semiconductor device 100 illustrated in FIGS. 1 to 5, except that bottom isolation patterns 170P1 and 170P2 and bottom sacrificial patterns 220P1 and 220P2 are introduced as a multilayer (e.g., bilayer) structure, the contact extension portion 280E of a lower contact structure 280A has a changed shape due to the bilayer structure, and some of the bottom isolation patterns 170P1 have a void VD. Description of aspects the same as or similar to those described above may be omitted.

The bottom isolation structure in one or more embodiments may be provided as a bilayer structure in a fin-type structure FS′. The fin-type structure FS' includes first and second fin-type patterns 105P1 and 105P2 sequentially disposed on an insulating pattern 210P of an insulating base layer 210. The first fin-type pattern 105P1 and the second fin-type pattern 105P2 may be semiconductor patterns. The first bottom isolation patterns 170P1 may be spaced apart from each other in the first direction (e.g., X-direction) below each of the plurality of gate structures GS, between the insulating base layer 210 and the first fin-type pattern 105P1, and the second bottom isolation patterns 170P2 may be spaced apart in the first direction (e.g., X-direction) below each of the plurality of gate structures GS, between the first fin-type pattern 105P1 and the second fin-type pattern 105P2. Each of the first and second bottom isolation patterns 170P1 and 170P2 may include the same material as a material of the internal spacers 170S.

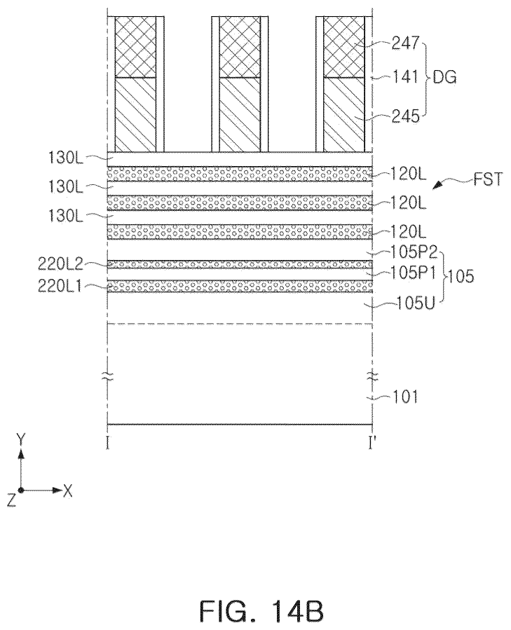

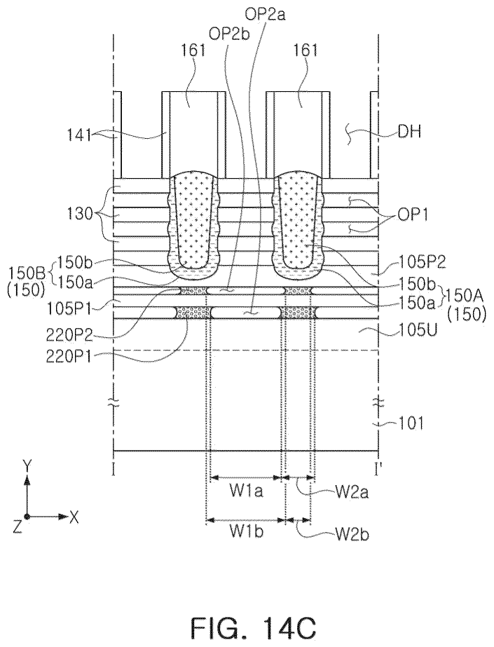

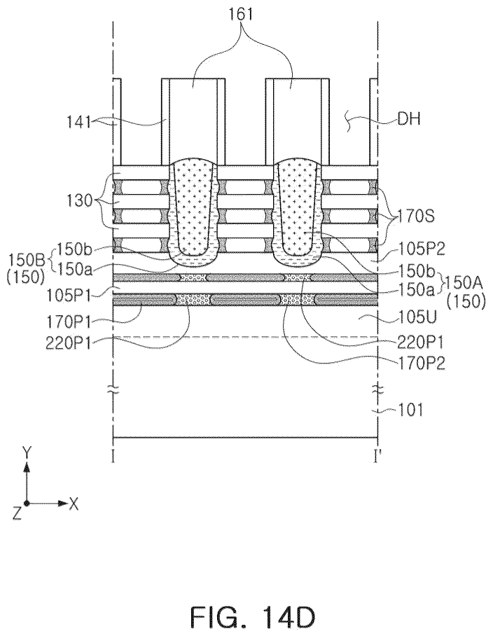

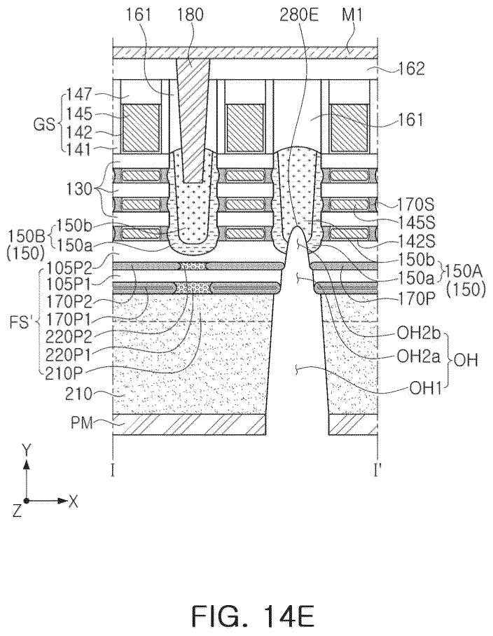

The first and second bottom isolation patterns 170P1 and 170P2 may have different thicknesses t1a and t1b and widths Wla and W1b. In one or more embodiments, a first thickness t1a of each of the first bottom isolation patterns 170P1 may be greater than a second thickness t1b of each of the second bottom isolation patterns 170P2. Each of the first and second thicknesses t1a and t1b may be smaller than the gap to between the plurality of channel layers 130. In addition, a first width W1a of each of the first bottom isolation patterns 170P1 in the first direction (e.g., X-direction) may be smaller than a second width W1b of each of the second bottom isolation patterns 170P2 in the first direction (e.g., X-direction). The widths Wla and W1b of the first and second bottom isolation patterns 170P1 and 170P2 may be adjusted using the respective thicknesses t1a and t1b. For example, in a sacrificial layer removal process (see FIG. 14C), since an etching amount (volume) of a sacrificial material is relatively constant, widths of removed gap regions OP2a and OP2b may also be adjusted differently by setting thicknesses of bottom sacrificial layers 220L1 and 220L2 differently.

A second source/drain pattern 150B may be connected to an upper contact structure 180, and the first bottom sacrificial pattern 220P1 may be disposed between first bottom isolation patterns adjacent to the second source/drain pattern 150B, among the first bottom isolation patterns 170P1. Similarly, the second bottom sacrificial pattern 220P2 may be disposed between bottom isolation patterns adjacent to the second source/drain pattern 150B, among the second bottom isolation patterns 170P2. Centers of each of the first bottom sacrificial pattern 220P1 and the second bottom sacrificial pattern 220P2 may approximately overlap each other in a direction (e.g., Z-direction) that is perpendicular to a center of the second source/drain pattern 150B (i.e., perpendicular to the first direction/X direction).

Similarly to the first and second bottom isolation patterns 170P1 and 170P2, a first thickness t1a of the first bottom sacrificial pattern 220P1 may be greater than a second thickness t1b of the second bottom sacrificial pattern 220P2. Furthermore, in contrast to the first and second bottom isolation patterns 170P1 and 170P2, a first width W2a of the first bottom sacrificial pattern 220P1 in the first direction (e.g., X-direction) may be greater than a second width W2b of the second bottom sacrificial pattern 220P2 in the first direction (e.g., X-direction).

The lower contact structure 280A may penetrate through the insulating base layer 210 and be connected to the first source/drain pattern 150A. As described above, the lower contact structure 280A may be defined by a gap between first bottom isolation patterns 170P1 adjacent to the first source/drain pattern 150A, among the first bottom isolation patterns 170P1, and a gap between second bottom isolation patterns 170P2 adjacent to the first source/drain pattern 150A, among the second bottom isolation patterns 170P2. Each of the gaps between the adjacent first and second bottom isolation patterns 170P1 and 170P2 may correspond to the widths of the first and second bottom sacrificial patterns 220P1 and 220P2. In one or more embodiments, centers of each of the gaps may approximately overlap each other in a direction (e.g., the Z-direction), perpendicular to a center of the first source/drain pattern 150A, and may thus be used as a self-alignment structure of the lower contact structure 280A.

In one or more embodiments, the gap between the adjacent second bottom isolation patterns 170P2 may be smaller than the gap between the adjacent first bottom isolation patterns 170P1. Referring to FIG. 8, due to the bilayer bottom isolation structure, the lower contact structure 280A may have two step portions ST1 and ST2. A first step portion ST1 may be provided in a region in which the contact extension portion 280E begins due to the gap between the adjacent first bottom isolation patterns 170P1, and a second step portion ST2 may be provided in an intermediate region of the contact extension portion 280E due to the gap between the adjacent second bottom isolation patterns 170P2.

At least one of the first and second bottom isolation patterns 170P1 and 170P2 may not be entirely filled, and a portion thereof may remain as the void VD. In one or more embodiments, the first bottom isolation patterns 170P1 may have the void VD.

FIG. 10 is a cross-sectional view illustrating a semiconductor device according to one or more embodiments.

Referring to FIG. 10, a semiconductor device 100C according to one or more embodiments may be understood as being similar to the semiconductor device 100 illustrated in FIGS. 1 to 5, except that the semiconductor device 100C includes a vertical sacrificial pattern 230P extending toward an insulating base layer 210 below a second source/drain pattern 150B, a fin-type pattern 105PA is provided as an insulating structure, and a lower contact structure 280A is formed without an insulating liner and a structure of a contact extension portion 280E′ is different. Description of aspects the same as or similar to those described above may be omitted.

The semiconductor device 100C according to one or more embodiments may further include a vertical sacrificial pattern 230P extending toward the insulating base layer 210 below the second source/drain pattern 150B. The vertical sacrificial pattern 230P may be introduced as a sacrificial structure for forming the lower contact structure 280A by forming a recessed portion to be deeper toward the fin-type pattern when forming the source/drain pattern (see FIG. 11C). For example, a fin-type pattern 105P may include silicon, and the vertical sacrificial pattern 230P may include silicon germanium. Bottom isolation patterns 170P adjacent to the second source/drain pattern 150B may extend into an interior of the vertical sacrificial patterns 230P. When forming a second gap region (see “OP2” in FIG. 12A) for the bottom isolation patterns 170P, both end regions of the second gap region may extend vertically in the vertical sacrificial pattern 230P, so that both ends of final bottom isolation patterns 170P may have a greater thickness than that of the other regions.

In one or more embodiments, the fin-type pattern 105PA may be provided as an insulating structure. For example, the fin-type pattern 105P may include silicon oxide. In one or more embodiments, the remaining active pattern may be oxidized through an oxidation process such as an additional thermal oxidation process and may be converted into a thermal oxide layer. In this case, the lower contact structure 280A may be provided without an insulating liner. The lower contact structure 280A may include a contact plug 285 and a conductive barrier 282 disposed on a surface of the contact plug 285. Since the lower contact structure 280A is formed in a space (corresponding to the dotted line area 280D) from which vertical sacrificial patterns disposed below a first source/drain pattern 150A are removed, the contact extension portion 280E may be somewhat expanded in a width direction.

A method of manufacturing a semiconductor device according to one or more embodiments may include a self-alignment process of the lower contact structure using the bottom sacrificial pattern between bottom isolation patterns. The method of manufacturing the semiconductor device 100 illustrated in FIGS. 1 to 5 may be described by referring to FIGS. 11A to 11D (forming the source/drain patterns), FIGS. 12A to 12D (forming the gate structure and the upper contact structure), and FIGS. 13A to 13D (forming the lower contact structure). FIGS. 11A to 11D, FIGS. 12A to 12D, and FIGS. 13A to 13D may be cross-sectional views corresponding to the cross-section illustrated in FIG. 2, respectively.

FIGS. 11A to 11D are cross-sectional views illustrating a method of manufacturing a semiconductor device according to one or more embodiments. That is, FIGS. 11A to 11D illustrate a process of forming source/drain patterns.

Referring to FIG. 11A, a bottom sacrificial layer 220L and a semiconductor layer 105′ may be sequentially formed on a substrate 101, and sacrificial layers 120L and semiconductor layers 130L may be alternately stacked on the semiconductor layer 105′.

The substrate 101 may include a semiconductor material, for example, a group IV semiconductor, a group III-V compound semiconductor, or a group II-VI compound semiconductor. For example, the group IV semiconductor may include silicon (Si), germanium (Ge), or silicon germanium (SiGe). The substrate 101 may include a bulk wafer, an epitaxial layer, or a silicon on insulator (SOI) layer.

The bottom sacrificial layer 220L and the semiconductor layer 105′ may be formed on the substrate 101, and the sacrificial layers 120L and the semiconductor layers 130L may be alternately stacked on the semiconductor layer 105′, thus forming a semiconductor stack body SL. The bottom sacrificial layer 220L and the sacrificial layers 120L may have a composition different from that of the semiconductor layers 105′ and 130L so as to have a selectivity with the semiconductor layers 105′ and 130L. The bottom sacrificial layer 220L may have a thickness t1 smaller than a thickness t0 of the sacrificial layers 120L. In a sacrificial pattern removal process (see FIG. 12A), since an etching amount (volume) of a sacrificial material is relatively constant, a thickness of the bottom sacrificial layer 220L may be formed to be smaller than a thickness of the sacrificial layers 120L, so that a width of a second gap region OP2 may be greater than a width of a first gap region OP1.

In one or more embodiments, the bottom sacrificial layer 220L and the sacrificial layers 120L may have a germanium concentration greater than the germanium concentration of the semiconductor layers 105′ and 130L. For example, the semiconductor layers 105′ and 130L may include silicon. The bottom sacrificial layer 220L and the sacrificial layers 120L may include silicon germanium having a relatively high germanium concentration (e.g., 15 atm % or more).

Next, referring to FIG. 11B, a semiconductor stack SL may be patterned into a plurality of fin-type structures FST extending in the first direction (e.g., X-direction), and a plurality of dummy gate structures DG extending in the second direction (e.g., Y-direction) may be formed.

In this process, portions of the semiconductor layer 105′, the bottom sacrificial layer 220L and the substrate 101 may be removed together with the sacrificial layers 120L and the semiconductor layers 130L, thus forming the fin-type structure FST extending in the first direction (e.g., X-direction). In the fin-type structure FST, portions of the semiconductor layer 105′ and the substrate 101 may be provided as a fin-type pattern 105. Next, as illustrated in FIGS. 3A to 3C, a device isolating layer 110 may be formed in a peripheral region of the fin-type structure.

Next, dummy gate structures DG and gate spacers 141 extending in the second direction (e.g., Y-direction) by intersecting the fin-type structure FST may be formed. The dummy gate structure DG may define a formation region of the gate structure GS. The dummy gate structure DG may be arranged at a constant pitch in the first direction (e.g., X-direction).

The dummy gate structure DG may include sacrificial gate layers 245 and a mask pattern 247 which are sequentially stacked. The sacrificial gate layer 245 may be patterned using the mask pattern 247. For example, the sacrificial gate layer 245 may include polysilicon. The sacrificial gate layer 245 may also be formed of a plurality of layers. The mask pattern 247 may include silicon oxide and/or silicon nitride. The gate spacers 141 may be formed on both sidewalls of the dummy gate structures DG. As described above, the gate spacers 141 may be formed of a low-K material, and may include, for example, at least one of SiO, SiN, SiCN, SiOC, SiON or SiOCN.

Next, referring to FIG. 11C, recessed portions RS may be formed by removing an exposed fin-type structure FST region from the dummy gate structures DG.

The dummy gate structures DG and the gate spacers 141 may be used as a mask to remove an exposed region of the fin-type structure FST, thus forming the recessed portions RS. The recessed portions RS may have a depth extending by a portion of the fin-type pattern 105P on the bottom sacrificial layer 220L. The channel layers 130 may have a channel length in the first direction (e.g., X-direction). Similar to the channel layers 130, the sacrificial patterns 120 may have a length corresponding to a length of the channel layers 130. In one or more embodiments, during a recess formation process or by an additional etching process, the sacrificial patterns 120 may be additionally removed to have an indentation ID.

As described in the example embodiment of FIG. 8, in this process, the recessed portion RS may be formed to have a depth extending to a level lower than a level of the bottom sacrificial layer 220L. In this case, a region additionally recessed in the fin-type pattern 105P may be provided as a space for forming vertical sacrificial patterns 230P, and before a process of forming the source/drain patterns (see FIG. 11D), the vertical sacrificial patterns 230P may be formed as an epitaxial layer. The vertical sacrificial patterns 230P may include a material having a selectivity with respect to a material of the substrate 101. For example, the substrate 101 may be silicon, and the vertical sacrificial patterns 230P may be silicon germanium (SiGe). The vertical sacrificial patterns 230P may have a relatively high germanium composition ratio (e.g., 15 at % or more) similarly to the sacrificial patterns 120.

Next, referring to FIG. 11D, an epitaxial layer growth process for the first and second source/drain patterns 150A and 150B may be performed.

An epitaxial layer may be grown from a bottom surface of the fin-type pattern 105P exposed by the recessed portions RS and side surfaces of the sacrificial patterns 120 and the channel layers 130, thus forming the first and second source/drain patterns 150A and 150B. The first and second source/drain patterns 150A and 150B may include impurities by in-situ doping. The first and second source/drain patterns 150A and 150B may be connected to the sacrificial patterns 120 and the channel layers 130 in the recessed portions RS. The first and second source/drain patterns 150A and 150B may have indented portions directed toward each of the sacrificial patterns 120.

The first and second source/drain patterns 150A and 150B may include a first epitaxial layer 150a and a second epitaxial layer 150b disposed on the first epitaxial layer 150a. In one or more embodiments, the first epitaxial layer 150a may directly contact side surfaces of the plurality of channel layers 130. In one or more embodiments, the first epitaxial layer 150a and the second epitaxial layer 150b may include different materials and/or impurities, as described above.

FIGS. 12A to 12D are cross-sectional views illustrating a method of manufacturing a semiconductor device according to one or more embodiments. That is, FIGS. 12A to 12D illustrate a process of forming a gate structure and an upper contact structure.

Referring to FIG. 12A, a first interlayer insulating layer 161 may be formed, and dummy gate structures DS and sacrificial patterns 120 may be removed.

The first interlayer insulating layer 161 may be formed to cover the dummy gate structures DG and first and second source/drain patterns 150A and 150B and may be formed by performing a flattening process. Through the flattening process, after a mask pattern 247 and a sacrificial gate layer 245 are removed, exposed sacrificial patterns 120 may be selectively removed. Accordingly, gate spaces DH from which the mask pattern 247 and the sacrificial gate layer 245 are removed, and first gap regions OP1 from which the sacrificial patterns are removed may be formed. The gate spaces DH and the first gap regions OP1 may be provided as spaces for forming a gate structure GS surrounding semiconductor patterns 130.

In this process, an exposed portion of the bottom sacrificial layer 220L after the mask pattern 247 and the sacrificial gate layer 245 are removed may also be removed together with the sacrificial patterns 120. The exposed portion of the bottom sacrificial layer 220L may be removed to form a second gap region OP2. Since a thickness of the bottom sacrificial layer 220L is smaller than a thickness of the sacrificial patterns 120, the bottom sacrificial layer 220L may be additionally etched in a width direction, i.e., in the first direction (e.g., X-direction). After this process, the remaining portions of the bottom sacrificial layer may be provided as bottom sacrificial patterns 220P between the second gap regions OP2. Centers of the bottom sacrificial patterns 220P may be aligned to overlap each other in a direction (e.g., Z-direction), substantially perpendicular to a center of the source/drain patterns 150. Accordingly, the bottom sacrificial patterns 220P may be advantageously used as a self-alignment structure for forming a lower contact structure 280.

Next, referring to FIG. 12B, a process of forming internal spacers 170S in the first gap regions OP1 may be performed.

The internal spacers 170S may be formed in each end of each of the first gap regions OP1 using a combination of a deposition process of an insulating material and a selective etching process. In this process, an insulating material of the internal spacers 170S may also be deposited in the second gap regions OP2, thus forming the bottom isolation pattern 170P. In one or more embodiments, an insulating material of the gate insulating film as well as an insulating material of the internal spacers 170S may also be additionally deposited on the second gap regions OP2 to form the bottom isolation patterns 170PA (see FIG. 6), or the second gap regions OP2 may not be entirely filled and the bottom isolation patterns 170P1 may have the void VD (see FIG. 10).

Next, referring to FIG. 12C, a gate structure GS surrounding semiconductor patterns 130 may be formed.

A gate insulating film 142 and a gate electrode 145 may be sequentially formed to form gate structures GS. In one or more embodiments, the gate insulating film 142 may conformally form the remaining spaces of the first gap regions OP1 in which the gate spaces DH and the internal spacers 170S are formed. After forming the gate insulating film 142, the remaining spaces may be filled with the gate electrode 145. After etching back the gate electrodes 145 in the gate regions DH, a gate capping layer 147 may be formed in the removed regions of the gate electrodes.

Next, referring to FIG. 12D, an upper contact structure 180 connected to the second source/drain pattern 150B may be formed, and a front-side interconnection structure 190 connected to the upper contact structure 180 may be formed.

After forming a second interlayer insulating layer 162, a contact hole connected to the second source/drain pattern 150B by penetrating through the first and second interlayer insulating layers 161 and 162 may be formed, and a conductive material may be filled in the contact hole, thus forming the second contact structure 180. A lower surface of the contact hole may extend into the second source/drain pattern 150B.

FIGS. 13A to 13D are cross-sectional views illustrating a method of manufacturing a semiconductor device according to one or more embodiments. That is, FIGS. 13A to 13D illustrate a process of forming a lower contact structure.

Referring to FIG. 13A, a portion of a substrate 101 below bottom isolation patterns 170P and bottom sacrificial patterns 220P may be selectively removed.

In the process of removing the substrate, the bottom isolation patterns 170P and the bottom sacrificial patterns 220P may be used as an etching stop layer. Before the process of removing the substrate 101, a process of polishing the substrate 101 by a certain thickness may first be performed. For example, the substrate 101 may be removed by a lapping, grinding, or polishing process and may be thinned. Next, the remaining region of the substrate may also be removed by a wet etching and/or oxidation process. In this process, the fin-type pattern portion 105U disposed below the bottom isolation patterns 170P and bottom sacrificial patterns 220P may also be removed.

Next, referring to FIG. 13B, an insulating base layer 210 may be formed in a region in which the substrate 101 is removed.

The insulating base layer 210 may be formed to cover the bottom isolation patterns 170P and the bottom sacrificial patterns 220P in the region from which the substrate 101 is removed. The insulating base layer 210 may have an insulating pattern 210P defined by a space disposed in a lower fin-type pattern 105′. The insulating pattern 210P may have a structure extending in the first direction (e.g., X-direction) (see FIG. 2). For example, the insulating base layer 210 may have SOH, FOX, TOSZ, USG, BSG, PSG, BPSG, PETEOS, FSG, HDP oxide, PEOX, FCVD oxide, or combinations thereof. The insulating base layer 210 may be formed using CVD, a fluid CVD process, or a spin coating process.

Next, referring to FIG. 13C, a contact hole OH connected to the first source/drain pattern 150A may be formed in the insulating base layer 210.

A photo mask PM may be formed on the insulating base layer 210, and the contact hole OH connected to the first source/drain pattern 150A may be formed using the photo mask PM. The contact hole OH may have a first hole portion OH1 penetrating through the insulating base layer 210 and a second hole portion OH2 extending from a region between the bottom isolation patterns 170P into the first source/drain pattern 150A. This process may include a first etching process for forming the first hole portion OH1 and a second etching process for forming the second hole portion OH2. The second etching process may be performed as an etching process for a semiconductor (e.g., silicon) after the bottom sacrificial pattern 220P is removed between the bottom isolation patterns 170P adjacent to the first source/drain pattern 150A after the first etching process. Since the second hole portion OH2 is formed in a region from which the bottom sacrificial pattern 220P precisely aligned in a direction, perpendicular to the first source/drain pattern 150A (e.g., the Z-direction), is removed, the second hole portion OH2 may be properly aligned with the first source/drain pattern 150A. The contact hole OH may have a step portion between the first hole portion OH1 and the second hole portion OH2, and a width of the second hole portion OH2 in the first direction (e.g., the X-direction) may be smaller than a width of the first hole portion OH1 in the first direction (e.g., the X-direction).

Next, referring to FIG. 13D, a lower contact structure 280 connected to the first source/drain pattern 150A may be formed in the contact hole OH.

In this process, an insulating liner 281 is formed on an internal surface of the contact hole, and a contact opening is formed to expose the first source/drain pattern. A contact plug 285 connecting to the first source/drain pattern is formed by formed a conductive material the contact opening. Accordingly, the lower contact structure 280 may be formed. For example, the contact plug 285 may include a conductive material such as Cu, Co, Mo, Ru, W, or an alloy thereof. For example, the insulating liner 281 may include SiO₂, SiN, SiCN, SiC, SiCOH, SiON, Al₂O₃, AlN, or combinations thereof.

The lower contact structure 280 may include a contact extension portion 280E passing through a region of the adjacent bottom isolation patterns 170P from the insulating base layer 210 and connected to the first source/drain pattern 150A. The contact extension portion may be disposed in the second hole portion. A width of a portion in which the contact extension portion 280E begins may be defined by a region of the adjacent bottom isolation patterns 170P in the first direction (e.g., X-direction), and, as described above, the lower contact structure 280 may have a step structure ST in the portion in which the contact extension portion 280E begins. A width of the contact extension portion 280E defined between the adjacent bottom isolation patterns 170P may be smaller than a width of another portion of the lower contact structure 280 adjacent to the insulating base layer 210.

Next, as illustrated in FIG. 2, the semiconductor device 100 may be provided by forming a back-side interconnection structure 290 connected to the lower contact structure 280.

FIGS. 14A to 14E are cross-sectional views illustrating a method of manufacturing a semiconductor device according to one or more embodiments. The method of manufacturing a semiconductor device shown in FIGS. 14A to 14E may be understood as a manufacturing process of the semiconductor device 100B illustrated in FIG. 8.

Referring to FIG. 14A, first and second bottom sacrificial layers 220L1 and 220L2 and first and second semiconductor layers 105a and 105b may be alternately stacking on a substrate 101, and sacrificial layers 120L and semiconductor layers 130L may be alternately stacked on a second semiconductor layer 105b, thus forming a semiconductor stack body SL.

The bottom sacrificial layer 220L and the sacrificial layers 120L may have compositions different from those of the first and second semiconductor layers 105a and 105b and the semiconductor layers 130L. In one or more embodiments, the first bottom sacrificial layer 220L1 may have a thickness greater than that of the second bottom sacrificial layer 220L2, and the first and second bottom sacrificial layers 220L1 and 220L2 may have thicknesses less than that of the sacrificial layers 120L.

In one or more embodiments, the first and second bottom sacrificial layers 220L1 and 220L2 and the sacrificial layers 120L may have a germanium concentration greater than a germanium concentration of the first and second semiconductor layers 105a and 105b and the semiconductor layers 130L. For example, the first and second semiconductor layers 105a and 105b and the semiconductor layers 130L may include silicon. The first and second bottom sacrificial layers 220L1 and 220L2 and the sacrificial layers 120L may include silicon germanium having a relatively high germanium concentration (e.g., 15 atm % or more).

Next, referring to FIG. 14B, a semiconductor stack SL may be patterned into a plurality of fin-type structures FST extending in the first direction (e.g., X-direction), and a plurality of dummy gate structures DG extending in the second direction (e.g., Y-direction) may be formed.

In this process, portions of the first and second bottom sacrificial layers 220L1 and 220L2, the first and second semiconductor layers 105a and 105b, and the substrate 101 may be removed along with the sacrificial layers 120L and the semiconductor layers 130L, thus forming the fin-type structures FST extending in the first direction (e.g., X-direction). In the fin-type structure FST, portions of the first and second semiconductor layers 105a and 105b and the substrate 101 may be provided as a fin-type pattern 105. Then, as illustrated in FIGS. 3A to 3C, a device isolating layer 110 may be formed in a peripheral region of the fin-type structure FST.

Next, dummy gate structures DG and gate spacers 141 extending in the second direction (e.g., Y-direction) by intersecting the fin-type structure FST may be formed. Then, a process of forming a series of source/drain patterns (see FIGS. 11C and 11D) may be performed.

Next, referring to FIG. 14C, a first interlayer insulating layer 161 may be formed to cover the dummy gate structures DG and first and second source/drain patterns 150A and 150B and may be formed by performing a flattening process. Through the flattening process, after removing a mask pattern 247 and a sacrificial gate layer 245, exposed sacrificial patterns 120 may be selectively removed.

Thereby, gate spaces DH from which the mask pattern 247 and the sacrificial gate layer 245 are removed, and first gap regions OP1 from which the sacrificial patterns are removed may be formed. The gate spaces DH and the first gap regions OP1 may be provided as spaces for forming a gate structure GS surrounding semiconductor patterns 130.

In this process, exposed portions of the first and second bottom sacrificial layers 220L1 and 220L2 after removing the mask pattern 247 and the sacrificial gate layer 245 may also be removed along with the sacrificial patterns 120. The exposed portions of the first and second bottom sacrificial layers 220L1 and 220L2 may be removed to form second lower gap regions OP2a and second upper gap regions OP2b. After this process, the remaining portions of the first bottom sacrificial layer 220L1 may be provided as first bottom sacrificial patterns 220P1 between the second lower gap regions OP2a, and the remaining portions of the second bottom sacrificial layer 220L2 may be provided as second bottom sacrificial patterns 220P2 between the second upper gap regions OP2b. Centers of the first and second bottom sacrificial patterns 220P1 and 220P2 may be aligned to overlap each other in a direction, substantially perpendicular to a center of source/drain patterns 150 (e.g., Z-direction). Accordingly, the first and second bottom sacrificial patterns 220P1 and 220P2 may be advantageously used as self-alignment structures for forming a lower contact structure 280.

Due to thickness conditions of the first and second bottom sacrificial layers 220L1 and 220L2, a first width W1a of each of the second bottom gap regions OP2a in the first direction (e.g., the X-direction) may be smaller than a second width W1b of each of the second bottom gap regions OP2b in the first direction (e.g., X-direction). In contrast, a first width W2a of each of the first bottom sacrificial patterns 220P1 in the first direction (e.g., X-direction) may be greater than a second width W2b of each of the second bottom sacrificial patterns 220P2 in the first direction (e.g., X-direction).

Next, referring to FIG. 14D, a process of forming internal spacers 170S in the first gap regions OP1 may be performed, and an insulating material of the internal spacers 170S may be deposited inside the second lower and upper gap regions OP2a and OP2b, thus forming first and second bottom isolation patterns 170P1 and 170P2. In one or more embodiments, the second upper gap regions OP2b may be approximately filled to form the second bottom isolation patterns 170P2, while the first bottom isolation patterns 170P1 formed in the second lower gap regions OP2a may have a void VD.

Next, a gate structure GS surrounding the semiconductor patterns 130 may be formed (see FIG. 12C), and an upper contact structure 180 connected to the second source/drain pattern 150B and a front-side interconnection structure 190 connected to the upper contact structure 180 may be formed (see FIG. 12D). Next, the first bottom isolation patterns 170P1 and the first bottom sacrificial patterns 220P1 may be used as etching stop layers, so that a portion of the substrate 101 may be selectively removed (see FIG. 13A), and an insulating base layer 210 may be formed in a region in which the substrate 101 is removed (see FIG. 13B).

Next, referring to FIG. 14E, a contact hole OH connected to the first source/drain pattern 150A may be formed in the insulating base layer 210.

A photo mask PM may be formed on the insulating base layer 210, and a contact hole OH connected to the first source/drain pattern 150A may be formed using the photo mask PM. The contact hole OH may have a first hole portion OH1 penetrating through the insulating base layer 210, a second hole portion OH2a between the first bottom isolation patterns 170P1 and the second bottom isolation patterns 170P2, and a third hole portion OH2b extending from a region between the second bottom isolation patterns 170P2 into the first source/drain pattern 150A. This process may include a first etching process of forming the first hole portion OH1, a second etching process of forming the second hole portion OH2a, and a third etching process forming the third hole portion OH2b. The second etching process may be performed as an etching process for a semiconductor (e.g., silicon) after performing the first etching process and then removing the first bottom sacrificial pattern 220P1 between the first bottom isolation patterns 170P1 adjacent to the first source/drain pattern 150A. The third etching process may be performed as an etching process for a semiconductor (e.g., silicon) after performing the second etching process and then removing the second bottom sacrificial pattern 220P2 between the second bottom isolation patterns 170P2 adjacent to the first source/drain pattern 150A. In one or more embodiments, some of the etching processes may be combined. For example, the second and third etching processes may be performed simultaneously. The contact hole OH may have a first step portion between the first hole portion OH1 and the second hole portion OH2a, and a second step portion between the second hole portion OH2a and the third hole portion OH2b. Through this process, the contact hole OH for the lower contact structure may be precisely aligned with the first source/drain pattern 150A. A lower contact structure 280 connected to the first source/drain pattern 150A may be formed in the precisely aligned contact hole OH. Then, as illustrated in FIG. 8, the semiconductor device 100B may be provided by forming the back-side interconnection structure 290 connected to the lower contact structure 280.

According to one or more embodiments, bottom isolation patterns may be introduced below channel layers and a gate structure, and a bottom contact structure may be self-alignment using a bottom sacrificial pattern disposed between the bottom isolation patterns.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device, comprising:
an insulating base layer;
a fin-type pattern on the insulating base layer and extending in a first direction;
a plurality of channel structures on the fin-type pattern and spaced apart from each other in the first direction, each of the plurality of channel structures comprising a plurality of channel layers spaced apart from each other in a second direction that is perpendicular to the first direction;
a plurality of gate structures respectively on the plurality of channel structures and extending in a third direction intersecting the first direction;
source/drain patterns comprising a first source/drain pattern that is connected to side surfaces of some of the plurality of channel structures;
internal spacers between the plurality of gate structures and the source/drain patterns;
a plurality of bottom isolation patterns respectively below the plurality of gate structures and between the insulating base layer and the fin-type pattern, the plurality of bottom isolation patterns being spaced apart from each other in the first direction, and comprising a material that is the same as a material of the internal spacers; and
a lower contact structure penetrating the insulating base layer and connected to the first source/drain pattern, the lower contact structure passing between first bottom isolation patterns among the plurality of bottom isolation patterns that are adjacent to the first source/drain pattern.

2. The semiconductor device of claim 1, wherein the source/drain patterns further comprise a second source/drain pattern, and
wherein the semiconductor device further comprises an upper contact structure connected to the second source/drain pattern.

3. The semiconductor device of claim 2, further comprising:
a bottom sacrificial pattern between second bottom isolation patterns among the plurality of bottom isolation patterns that are adjacent to the second source/drain pattern.

4. The semiconductor device of claim 3, wherein, in the first direction, a width the bottom sacrificial pattern is smaller than a width of each of the second bottom isolation patterns that are adjacent to the second source/drain pattern.

5. The semiconductor device of claim 3, wherein, in the first direction, a width of the bottom sacrificial pattern is substantially the same as a width of a portion of the lower contact structure that is between the first bottom isolation patterns that are adjacent to the first source/drain pattern.

6. The semiconductor device of claim 3, wherein each of the plurality of channel layers comprises silicon, and
wherein the bottom sacrificial pattern includes silicon germanium.

7. The semiconductor device of claim 3, further comprising:
a vertical sacrificial pattern below the second source/drain pattern and extending toward the insulating base layer,
wherein each of the second bottom isolation patterns adjacent to the second source/drain pattern comprises a portion extending into the vertical sacrificial pattern.

8. The semiconductor device of claim 1, wherein a portion of the lower contact structure between the first bottom isolation patterns adjacent to the first source/drain pattern has a width that is smaller than a width of portions of the lower contact structure that are below the first bottom isolation patterns adjacent to the first source/drain pattern.

9. The semiconductor device of claim 1, wherein the lower contact structure comprises a contact plug and an insulating liner electrically isolated between the contact plug and the fin-type pattern.

10. The semiconductor device of claim 1, wherein each of the plurality of bottom isolation patterns has a thickness that is smaller than a gap between the plurality of channel layers.

11. The semiconductor device of claim 10, wherein each of the plurality of bottom isolation patterns has a width in the first direction that is greater than a width of the plurality of channel layers in the first direction.

12. The semiconductor device of claim 1, wherein at least one of the plurality of bottom isolation patterns comprises a void.

13. The semiconductor device of claim 1, wherein each of the internal spacers has at least one side surface contacting at least one gate insulating portion of the gate structure, and
wherein the side surfaces of each of the internal spacers has a concave side surface.

14. The semiconductor device of claim 1, wherein in a cross-section in the first direction, an upper end and a lower end in the second direction of each of the internal spacers are wider than a middle portion thereof.

15. A semiconductor device, comprising:
an insulating base layer;
a fin-type structure on the insulating base layer and extending in a first direction;
a plurality of channel structures on the fin-type structure and spaced apart from each other in the first direction, and each of the plurality of channel structures comprising a plurality of channel layers spaced apart from each other in a second direction perpendicular to the first direction;
a plurality of gate structures respectively on the plurality of channel structures and extending in a third direction intersecting the first direction;
source/drain patterns comprising a first source/drain pattern that is connected to side surfaces of some of the plurality of channel structures;
internal spacers between the plurality of gate structures and the source/drain patterns; and
a lower contact structure penetrating the insulating base layer and connected to the first source/drain pattern,
wherein the fin-type structure comprises:
a first fin-type pattern and a second fin-type pattern on the insulating base layer,
a plurality of first bottom isolation patterns respectively below the plurality of gate structures and spaced apart from each other in the first direction, the plurality of first bottom isolation patterns being between the insulating base layer and the first fin-type pattern, and
a plurality of second bottom isolation patterns respectively below the plurality of gate structures and spaced apart from each other in the first direction, the plurality of second bottom isolation patterns being between the first fin-type pattern and the second fin-type pattern,
wherein each of the plurality of first bottom isolation patterns and the plurality of second bottom isolation patterns comprises a material that is the same as a material of the internal spacers, and
wherein the lower contact structure penetrates between third bottom isolation patterns among the plurality of first bottom isolation patterns that are adjacent to the first source/drain pattern, and between fourth bottom isolation patterns among the plurality of second bottom isolation patterns that are adjacent to the first source/drain pattern.

16. The semiconductor device of claim 15, wherein the source/drain patterns further comprise a second source/drain pattern,
wherein the semiconductor device further comprises an upper contact structure connected to the second source/drain pattern, and
wherein the fin-type structure further comprises:
a first bottom sacrificial pattern between fifth bottom isolation patterns among the plurality of first bottom isolation patterns that are adjacent to the second source/drain pattern, and
a second bottom sacrificial pattern disposed between sixth bottom isolation patterns among the plurality of second bottom isolation patterns that are adjacent to the second source/drain pattern.

17. The semiconductor device of claim 15, wherein a first thickness of each of the plurality of first bottom isolation patterns is greater than a second thickness of each of the plurality of second bottom isolation patterns, and
wherein the first thickness and the second thickness is smaller than a gap between the plurality of channel layers.

18. The semiconductor device of claim 17, wherein, in the first direction, a first width of each of the plurality of first bottom isolation patterns is smaller than a second width of each of the plurality of second bottom isolation patterns.

19. The semiconductor device of claim 15, wherein at least one bottom isolation pattern of the plurality of first bottom isolation patterns and the plurality of second bottom isolation patterns comprises a void.

20. A semiconductor device, comprising:
an insulating base layer;
a plurality of channel layers on the insulating base layer and spaced apart from each other;
a gate structure surrounding the plurality of channel layers;
a first source/drain pattern and a second source/drain pattern on the insulating base layer;
internal spacers in the gate structure and between the plurality of channel layers and the first source/drain pattern and the second source/drain pattern;
a bottom isolation pattern on an upper surface of the insulating base layer and below the plurality of channel layers, the bottom isolation pattern comprising a material that is the same as a material of the internal spacers;
a first contact structure penetrating the insulating base layer, contacting a first side of the bottom isolation pattern and connected to the first source/drain pattern;
a second contact structure connected to the second source/drain pattern; and
a bottom sacrificial pattern below the second source/drain pattern, on a level that is the same as a level of the bottom isolation pattern, and connected to a second side of the bottom isolation pattern.
